(19) United States
(12) Patent Application Publication
(10) Pub. No.: US 2026/0235658 A1
(43) Pub. Date: Aug. 13, 2026

(54) METHOD OF INSPECTING A DISPLAY DEVICE AND ELECTRONIC DEVICE COMPRISING THE DISPLAY DEVICE

(71) Applicant: Samsung Display Co., Ltd., Yongin-si (KR)

(72) Inventors: Geun Hyuk CHOI, Yongin-si (KR); Jung Hwa PARK, Yongin-si (KR); Jae Han LEE, Yongin-si (KR)

(21) Appl. No.: 19/180,643

(22) Filed: Apr. 16, 2025

(30) Foreign Application Priority Data
May 2, 2024 (KR) 10-2024-0058579

(51) Int. Cl. G01R 31/26; G01R 31/52; H10P 74/20

(52) U.S. Cl. CPC G01R 31/2635; G01R 31/52; H10P 74/207

(57) ABSTRACT

A method of inspecting a display device includes providing an inspection-target display device including a substrate including first and second surfaces, and first and second sub-pixels formed on the first surface. The method includes performing an etching process in a direction from the second surface toward the first surface and performing an inspection process on the first and second sub-pixels, wherein the first sub-pixel may include a first anode electrode, and a first contactor electrically connected to the first anode electrode and wherein the second sub-pixel may include a second anode electrode, and a second contactor electrically connected to the second anode electrode. Performing the etching process may include exposing the first and second contactors and performing the inspection process may include bringing a first probe into electrical contact with the first contactor and bringing a second probe into electrical contact with the second contactor.

This application claims priority to Korean Patent Application No. 10-2024-0058579, filed on May 02, 2024, and all the benefits accruing therefrom under 35 U.S.C. §119, the content of which in its entirety is herein incorporated by reference.

### BACKGROUND

### Field of Invention

The invention relates to a display device, and more particularly to a method of inspecting a display device and an electronic device comprising the display device.

### Description of Related Art

As interest in information displays increases, research and development on display devices have been continuously conducted.

The display devices may include sub-pixels where each of the sub-pixels include an organic light emitting diode (OLED). Due to leakage current (e.g., lateral leakage) occurring between sub-pixels, there may be a risk of crosstalk between electrical signals.

### SUMMARY

An aspect of the invention may provide a method of inspecting a display device and an electronic device comprising the display device, in which information about leakage current can be clearly identified.

In an embodiment, a method of inspecting a display device is provided and includes providing an inspection-target display device including a substrate including a first surface and a second surface, and a first sub-pixel and a second sub-pixel formed on the first surface of the substrate to be disposed adjacent to each other. The method includes performing an etching process in a direction from the second surface toward the first surface and performing an inspection process on the first sub-pixel and the second sub-pixel, where the first sub-pixel may include a first anode electrode and a first contactor electrically connected to the first anode electrode, and the second sub-pixel may include a second anode electrode and a second contactor electrically connected to the second anode electrode. Performing the etching process may include exposing the first contactor and the second contactor and performing the inspection process may include bringing a first probe into electrical contact with the first contactor, and bringing a second probe into electrical contact with the second contactor.

In an embodiment, the method may further include performing a pretreatment process on the substrate before performing the etching process, where performing the pretreatment process may include reducing a thickness of the substrate.

In an embodiment, the pretreatment process may include a polishing process or an etching process.

In an embodiment, the substrate may include silicon.

In an embodiment, after the pretreatment process is performed, the substrate may have a thickness ranging from about 100 μm to about 200 μm.

In an embodiment, the inspection-target display device may further include a buffer layer on the substrate, an interlayer conductive layer on the buffer layer, and an insulating layer on the interlayer conductive layer. Performing the etching process may include etching at least a portion of each of the substrate, the buffer layer, the interlayer conductive layer, and the insulating layer.

In an embodiment, performing the etching process may include performing a first etching process, where performing the first etching process may include forming a cavity in the substrate such that the buffer layer is not exposed.

In an embodiment, a depth of the cavity may range from about 50 μm to about 90 μm.

In an embodiment, performing the etching process may include performing a second etching process, where performing the second etching process may include removing at least a portion of each of the substrate and the buffer layer such that at least a portion of the interlayer conductive layer is exposed.

In an embodiment, performing the etching process may include performing a third etching process, where performing the third etching process may include removing at least a portion of the insulating layer such that the first contactor and the second contactor are exposed.

In an embodiment, the interlayer conductive layer may include a first conductive layer, a second conductive layer, and a third conductive layer that are sequentially stacked. Performing the third etching process may include etching the first conductive layer, the second conductive layer and the third conductive layer.

In an embodiment, each of the first probe and the second probe may include a nanoprobe or a microprobe.

In an embodiment, each of the first probe and the second probe may have a thickness that is less than a thickness of each of the first contactor and the second contactor.

In an embodiment, each of the first probe and the second probe may include a tip having a size ranging from about 5 nm to about 15 nm.

In an embodiment, performing the inspection process may include determining information about leakage current between the first sub-pixel and the second sub-pixel, based on quantitative information acquired by the first probe and the second probe.

In an embodiment, the first sub-pixel may include a first light emitting element including the first anode electrode and the second sub-pixel may include a second light emitting element including the second anode electrode. Performing the inspection process may include measuring a magnitude of a first current applied to the first light emitting element, and measuring a magnitude of a second current applied to the second light emitting element.

In an embodiment, the quantitative information may include the magnitude of the first current and the magnitude of the second current.

In an embodiment, the inspection-target display device may be configured to emit light in a direction from the second surface toward the first surface.

In an embodiment, the inspection-target display device may further include an emission structure disposed on the first anode electrode and the second anode electrode, wherein the emission structure is directed in a direction from the second surface toward the first surface. Performing the etching process may include exposing the first contactor and the second contactor without removing the emission structure.

In an embodiment, the emission structure may have a tandem structure.

In an embodiment, an electronic device may comprise: a processor configured to provide input image data; the inspection-target display device, the inspection-target display device being configured to display an image based on the input image data, the display device including sub-pixel areas; and a power supply configured to supply power to the display device.

### BRIEF DESCRIPTION OF THE DRAWINGS

The above and other features of the invention will become more apparent by describing in further detail embodiments thereof with reference to the accompanying drawings, in which:

FIG. 1 is a schematic plan view illustrating an inspection-target display device, in accordance with an embodiment.

FIG. 2 is a flowchart illustrating a method of inspecting the display device, in accordance with an embodiment.

FIG. 3 is a schematic sectional view of the inspection-target display device illustrating, by process steps, the method of inspecting the display device, in accordance with an embodiment.

FIG. 4 is a schematic sectional view of the inspection-target display device illustrating, by process steps, the method of inspecting the display device, in accordance with an embodiment.

FIG. 5 is a schematic sectional view of the inspection-target display device illustrating, by process steps, the method of inspecting the display device, in accordance with an embodiment.

FIG. 6 is a schematic sectional view of the inspection-target display device illustrating, by process steps, the method of inspecting the display device, in accordance with an embodiment.

FIG. 7 is a schematic sectional view of the inspection-target display device illustrating, by process steps, the method of inspecting the display device, in accordance with an embodiment.

FIG. 8 is a schematic sectional view of the inspection-target display device illustrating, by process steps, the method of inspecting the display device, in accordance with an embodiment.

FIG. 9 is a schematic block diagram illustrating an electronic device including a display device in accordance with an embodiment.

FIG. 10 is a schematic diagram illustrating an example where the electronic device of FIG. 9 is implemented as a smartphone.

FIG. 11 is a schematic diagram illustrating an example where the electronic device of FIG. 9 is implemented as a tablet computer.

### DETAILED DESCRIPTION

As the present disclosure allows for various changes and numerous embodiments, particular embodiments will be illustrated in the drawings and described in detail in the written description. However, this is not intended to limit the invention to particular modes of practice, and it is to be appreciated that all changes, equivalents, and substitutes that do not depart from the spirit and technical scope of the invention are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element. In the present disclosure, the singular forms are intended to include the plural forms as well, unless the context clearly indicates otherwise.

It will be further understood that the terms “comprise”, “include”, “have”, etc. when used in the present disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part, but a third part may intervene between them.

Various embodiments of the invention relates to a method of inspecting a display device and an electronic device comprising the display device. Hereinafter, a method of inspecting a display device and an electronic device comprising the display device, in accordance with an embodiment, will be described with reference to the attached drawings.

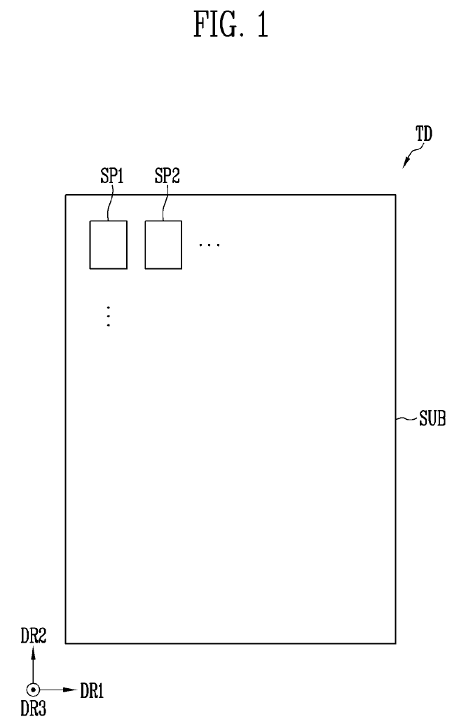

FIG. 1 is a schematic plan view illustrating an inspection-target display device TD, in accordance with an embodiment.

In an embodiment and referring to FIG. 1, an inspection-target display device TD may be provided, where the inspection-target display device TD may include a substrate SUB, and a first sub-pixel SP1 and a second sub-pixel SP2 disposed (e.g., formed) on the substrate SUB.

In an embodiment, the inspection-target display device TD may be a target device on which an inspection process, based on a method of inspecting the display device in accordance with an embodiment, is performed.

In an embodiment, the inspection-target display device TD may be a sample device provided for the display device inspecting method or the inspection-target display device may be a display device provided to be normally operated after the display device inspecting method is performed. However, the invention is not limited to a specific embodiment.

In an embodiment, the substrate SUB may form a base surface of the inspection-target display device TD, where the substrate SUB may be a rigid or flexible substrate or film. For example, the substrate SUB may include glass material. In another embodiment, the substrate SUB may include silicon material. In still yet another embodiment, the substrate SUB may include polyimide. However, the invention is not limited to the aforementioned embodiment.

In an embodiment, the inspection-target display device TD may be configured to emit light. For example, the inspection-target display device TD may include first and second sub-pixels SP1 and SP2, respectively, on the substrate SUB, where the sub-pixels SP1 and SP2 may be disposed adjacent to each other. Each of the sub-pixels SP1 and SP2 may emit light having a certain wavelength.

For convenience of explanation, only the sub-pixels SP1 and SP2 are illustrated in FIG. 1, but the inspection-target display device TD may include a red sub-pixel, a green sub-pixel, and a blue sub-pixel, and any two adjacent sub-pixels among various sub-pixels may be defined as the first and second sub-pixels SP1 and SP2, respectively.

In an embodiment, the first and second sub-pixels SP1 and SP2 may be disposed adjacent to each other in the first direction DR1. However, the present disclosure is not limited to the aforementioned example. The sub-pixels SP1 and SP2 may also be disposed adjacent to each other in the second direction DR2.

In an embodiment, the first direction DR1 and the second direction DR2 may define a plane on which the substrate SUB is disposed. In the present disclosure, the third direction DR3 may correspond to a thickness direction of the substrate SUB and may correspond to a direction in which light is outputted when the inspection-target display device TD emits light.

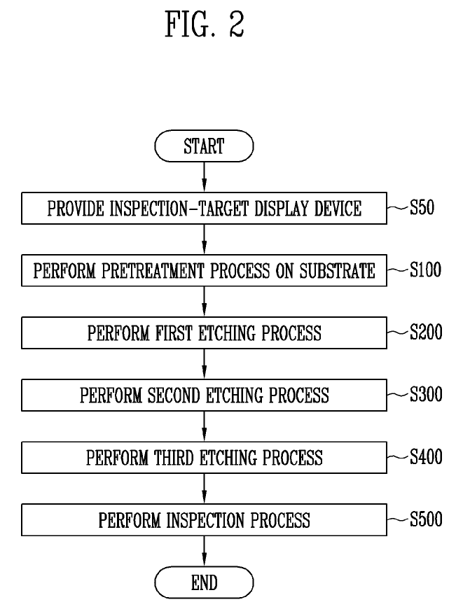

Hereinafter, the display device inspecting method for the inspection-target display device TD, in accordance with an embodiment, will be described with reference to FIGS. 2 to 7.

FIG. 2 is a flowchart illustrating the display device inspecting method, in accordance with an embodiment.

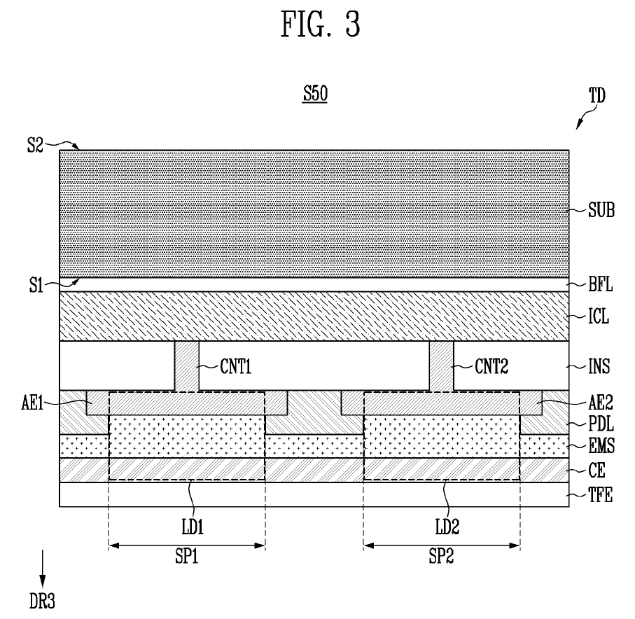

FIGS. 3 to 8 are schematic sectional views illustrating, by process steps, the method of inspecting the display device, in accordance with an embodiment.

In an embodiment and referring to FIG. 2, the display device inspecting method may include step S50 of providing an inspection-target display device, step S100 of performing a pretreatment process on a substrate, step S200 of performing a first etching process, step S300 of performing a second etching process, step S400 of performing a third etching process, and step S500 of performing an inspection process. In an embodiment and referring to FIGS. 2 and 3, at step S50 of providing the inspection-target display device, the inspection-target display device TD including a plurality of layers may be provided on the substrate SUB.

In an embodiment, the inspection-target display device TD may include a substrate SUB, a buffer layer BFL, an interlayer conductive layer ICL, an insulating layer INS, first and second contactors CNT1 and CNT2, respectively, first and second anode electrodes AE1 and AE2, respectively, a pixel defining layer PDL, an emission structure EMS, a cathode electrode CE, and an encapsulation layer TFE.

In an embodiment, the substrate SUB may include a first surface S1 and a second surface S2. The plurality of layers on the substrate SUB may be disposed on the first surface S1 of the substrate SUB. The first surface S1 may be a front surface of the substrate SUB. The second surface S2 may be a rear surface of the substrate SUB. In an embodiment, the inspection-target display device TD may be configured to emit light in a direction from the second surface S2 toward the first surface S1.

In an embodiment, the buffer layer BFL may be disposed between semiconductor portions included in the inspection-target display device TD and the substrate SUB, and may include an inorganic material such as silicon oxide.

In an embodiment, the interlayer conductive layer ICL may be disposed on the buffer layer BFL and may be electrically connected to the pixel circuit in another portion of the inspection-target display device TD.

The interlayer conductive layer ICL may include various conductive materials. For example, in an embodiment, the interlayer conductive layer ICL may include conductive materials such as titanium (Ti), copper (Cu), and aluminum (Al). However, the invention is not limited to the aforementioned example. The interlayer conductive layer ICL may also include a multilayer structure. For example, the interlayer conductive layer ICL may include a first conductive layer on the buffer layer BFL, a second conductive layer on the first conductive layer, and a third conductive layer on the second conductive layer.

In an embodiment, the first conductive layer may include titanium (Ti), the second conductive layer may include aluminum (Al) or copper (Cu), and the third conductive layer may include titanium (Ti). However, the invention is not limited to the aforementioned embodiment. In an embodiment, the insulating layer INS may be disposed on the interlayer conductive layer ICL, where the insulating layer INF may include various insulating materials. For example, in an embodiment, the insulating layer INS may include an inorganic material such as silicon oxide. However, the invention is not limited to the aforementioned embodiment.

In an embodiment, the contactors CNT1 and CNT2 may pass through the insulating layer INS. The contactors CNT1 and CNT2 may be conductive structures formed through the same process as the anode electrodes AE1 and AE2 and may be electrically connected to the interlayer conductive layer ICL.

In an embodiment, the anode electrodes AE1 and AE2 may be disposed on the insulating layer INS, and may be electrically connected to the interlayer conductive layer ICL through the contactors CNT1 and CNT2, respectively. For example, the first anode electrode AE1 may be electrically connected to a first portion of the interlayer conductive layer ICL through the first contactor CNT1 and the second anode electrode AE2 may be electrically connected to a second portion of the interlayer conductive layer ICL through the second contactor CNT2. For convenience of explanation , in FIG. 3, the first and second portions of the interlayer conductive layer ICL are illustrated as being successively disposed, but the first and second portions of the interlayer conductive layer ICL may be separated from each other.

In an embodiment, the anode electrodes AE1 and AE2 may include various conductive materials. For example, the anode electrodes AE1 and AE2 may include transparent conductive material. In an embodiment, the anode electrodes AE1 and AE2 may include opaque conductive material capable of reflecting light. For example, the anode electrodes AE1 and AE2 may include one or more selected from the group consisting of titanium nitride (TiN), silver (Ag), and aluminum (Al). However, the invention is not limited to the aforementioned embodiment.

In an embodiment, the pixel defining layer PDL may partially cover portions of the anode electrodes AE1 and AE2 while exposing other portions of the anode electrodes AE1 and AE2. The pixel defining layer PDL may include inorganic materials such as silicon oxide and silicon nitride. However, the invention is not limited to the aforementioned embodiment.

In an embodiment, the emission structure EMS may be disposed on the anode electrodes AE1 and AE2 in a direction from the second surface S2 to the first surface S1. In an embodiment, the emission structure EMS may be disposed over the sub-pixels SP1 and SP2 and may include a plurality of layers. For example, the emission structure EMS may include an emission unit including a hole transport component, an emission component (or a light generating layer), and an electron transport component. Each of the layers that form the emission structure EMS may include an organic material and, in an embodiment, may further include an inorganic material such as a metal-containing compound or quantum dot.

In an embodiment, the cathode electrode CE may be disposed on the emission structure EMS to be directed in a direction from the second surface S2 toward the first surface S1. The cathode electrode CE may be a common electrode for the sub-pixels SP1 and SP2. In an embodiment, the cathode electrode CE may include a transparent conductive material and may be a conductive thin film including a conductive material such as silver (AG). However, the invention is not limited to the aforementioned embodiment. first and sec

In an embodiment, the first anode electrode AE1, a portion of the emission structure EMS, and a portion of the cathode electrode CE may form a first light emitting element LD1 included in the first sub-pixel SP1. The second anode AE2, another portion of the emission structure EMS, and another portion of the cathode electrode CE may form a second light emitting element LD2 included in the second sub-pixel SP2.

In an embodiment, the encapsulation layer TFE may be disposed on the cathode electrode CE, where the encapsulation layer TFE may encapsulate layers provided under the encapsulation layer TFE. The encapsulation layer TFE may include various inorganic materials or organic materials. In an embodiment, the encapsulation layer TFE may have a multilayer structure.

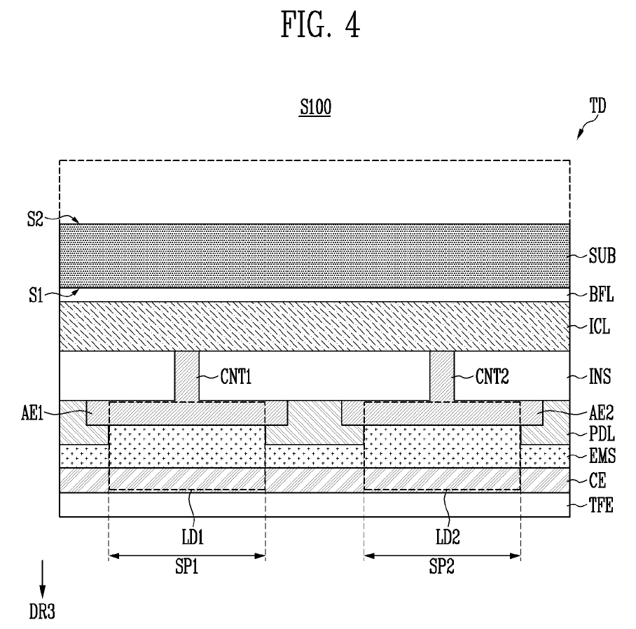

In an embodiment and referring to FIGS. 2 and 4, at step S100 of performing a pretreatment process on the substrate, the pretreatment process may be applied to the second surface S2 of the substrate SUB.

In an embodiment, at the present step S100, the pretreatment process may be a polishing process on the second surface S2 of the substrate SUB. In another embodiment, the pretreatment process may be an etching process on the second surface S2 of the substrate SUB.

In an embodiment, at the present step S100, at least a portion of the substrate SUB may be removed so that the substrate SUB may be provided to have a relatively small thickness. For example, in an embodiment, as the present step S100 is performed, the substrate SUB may have a thickness of about 200 μm or less. For example, in another embodiment, as the present step S100 is performed, the substrate SUB may have a thickness ranging from about 100 μm to about 200 μm.

In an embodiment, after step S100 of performing the pretreatment process on the substrate is performed, a plurality of etching processes may be performed. The plurality of etching processes performed after step S100 of performing the pretreatment process on the substrate is performed may be carried out in a direction from the second surface S2 toward the first surface S1. In an embodiment, each of the plurality of etching processes may be a dry etching process.

According to an embodiment, the plurality of etching processes after step S100 of performing the pretreatment process on the substrate may include the step of exposing the contactors CNT1 and CNT2 to perform an inspection process on the inspection-target display device TD.

Hereinafter, for convenience of explanation, the following description will be provided based on an embodiment in which the plurality of etching processes for exposing the contactors CNT1 and CNT2 include first to third etching processes.

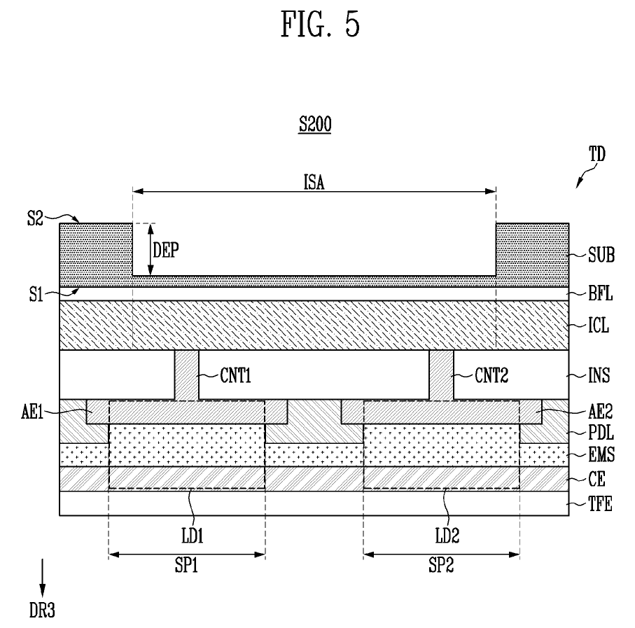

In an embodiment and referring to FIGS. 2 and 5, at step S200 of performing the first etching process, at least a portion of the substrate SUB may be etched.

In an embodiment, at the present step S200, a portion of the substrate SUB in an inspection-target area ISA may be removed, so that a cavity may be formed in the substrate SUB. At the present step S200, the buffer layer BFL may not be exposed and a depth DEP of an area (e.g., a cavity) formed in the inspection-target area ISA by removing a portion of the substrate SUB may range from about 50 μm to about 90 μm.

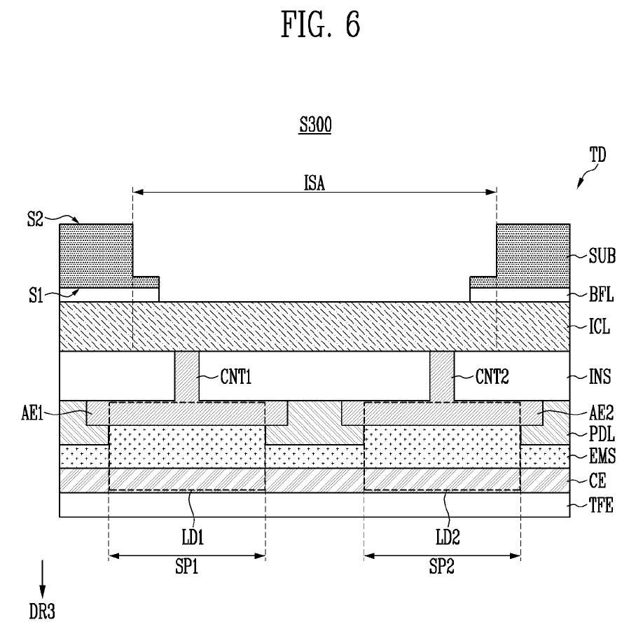

In an embodiment and referring to FIGS. 2 and 6, at step S300 of performing the second etching process, at least portions of the substrate SUB and the buffer layer BFL may be etched.

At the present step S300, the substrate SUB and the buffer layer BFL in the inspection-target area ISA may be etched. Consequently, at least a portion of the interlayer conductive layer ICL in the inspection-target area ISA may be exposed.

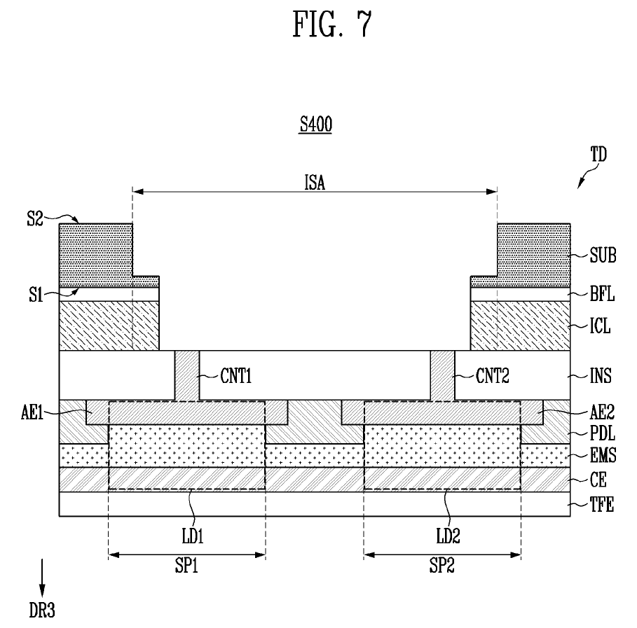

In an embodiment and referring to FIGS. 2 and 7, at step S400 of performing the third etching process, at least a portion of the interlayer conductive layer ICL may be etched.

At the present step S400, the interlayer conductive layer ICL in the inspection-target area ISA may be etched. Hence, the contactors CNT1 and CNT2 in the inspection-target area ISA may be exposed.

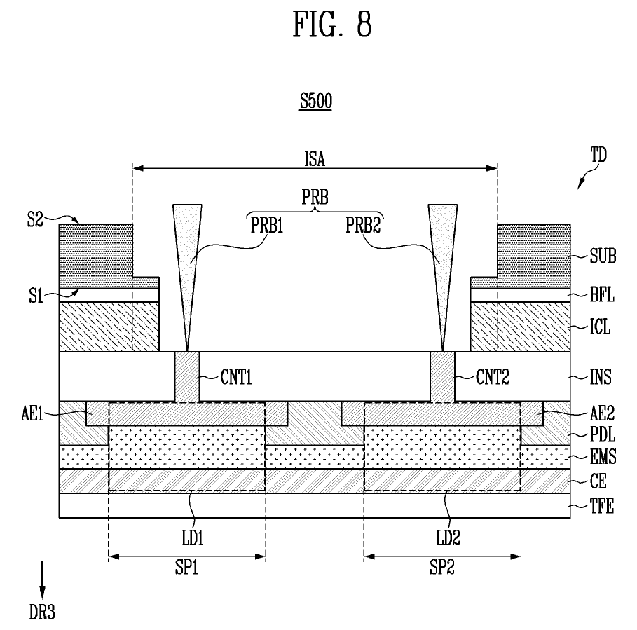

In an embodiment, the inspection-target area ISA may be an area where the contactors CNT1 and CNT2 are disposed and may be an area where probes PRB (See FIG. 8) are provided.

In an embodiment, the third etching process may include a plurality of etching steps. For example, in the case where the interlayer conductive layer ICL includes the first to third conductive layers that are sequentially stacked, the third etching process may include the step of etching the first and second conductive layers and the step of etching the third conductive layer.

In an embodiment and referring to FIGS. 2 and 8, at step S500 of performing the inspection process, an inspection process on the sub-pixels SP1 and SP2 may be performed using probes PRB.

At the present step S500, the probes PRB may be provided in the inspection-target area ISA and may electrically contact the exposed first and second contactors CNT1 and CNT2, respectively. For example, the probes PRB may include a first probe PRB1 and a second probe PRB2, where the first probe PRB1 may be electrically connected to the first contactor CNT1 and the second PRB2 may be electrically connected to the second contactor CNT2.

In an embodiment, each of the probes PRB may include a tip, and may be a nanoprobe or a microprobe. The probes PRB may each have a thickness that is less than that of the contactors CNT1 and CNT2. In an embodiment, the size (e.g., the diameter) of the tip of each of the probes PRB may be about 15 nm or less. For example, in an embodiment, the size (e.g., the diameter) of the tip of each of the probes PRB may range from about 5 nm to about 15 nm. However, the invention is not limited to the aforementioned embodiment.

At the present step S500, the magnitude of current flowing to the light emitting elements LD1 and LD2 when the sub-pixels SP1 and SP2 emit light may be measured using the probes PRB. For example, the probes PRB may be included in a current measurement device. Current flowing to the light emitting elements LD1 and LD2 may be applied to the probes PRB. Based on information about the magnitude of current applied to the probes PRB, the current measurement device may determine the magnitude of current flowing to the first and second light emitting elements LD1 and LD2.

According to an embodiment, since the first probe PRB1 may be electrically connected to the first anode electrode AE1 through the first contactor CNT1, the magnitude of current applied to the first light emitting element LD1 may be measured when the first sub-pixel SP1 and the second sub-pixel SP2 emit light. According to an embodiment, since the second probe PRB2 may be electrically connected to the second anode electrode AE2 through the second contactor CNT2, the magnitude of current applied to the second light emitting element LD2 may be measured when the first sub-pixel SP1 and the second sub-pixel SP2 emit light.

In an embodiment, based on the determined magnitude of current flowing to the light emitting elements LD1 and LD2, the magnitude of leakage current between the sub-pixels SP1 and SP2 may be quantitatively measured. For example, the magnitude of leakage current may be determined by comparing the magnitude of current in the first light emitting element LD1 measured using the first probe PRB1 with the magnitude of current intended in the first light emitting element LD1 in the case where no leakage current occurs between the sub-pixels SP1 and SP2. For example, in the case where no leakage current occurs between the sub-pixels SP1 and SP2, the magnitude of leakage current may be determined by comparing the magnitude of current in the second light emitting element LD2 measured using the second probe PRB2 with the magnitude of current intended in the second light emitting element LD2.

According to an embodiment, as described above, since information about leakage current between the sub-pixels SP1 and SP2 disposed adjacent to each other may be quantitatively determined, the information about the leakage current may be clearly identified. For example, the magnitude of a first current measured by the first probe PRB1 through the first contactor CNT1 and the magnitude of a second current measured by the second probe PRB2 through the second contactor CNT2 may correspond to quantitative information. Based on the magnitudes of the first current and the second current, information about leakage current may be thoroughly analyzed.

In an embodiment, to measure current for the first and second light emitting elements LD1 and LD2, there may be a need to bring the probes PRB1 and PRB2 into contact with distinct electrical paths.

In an embodiment, to acquire information about current flowing to the light emitting elements LD1 and LD2, layers provided under the contactors CNT1 and CNT2 may be exposed. In this case, information about current flowing to the light emitting elements LD1 and LD2 may be acquired without causing damage to the emission structure EMS.

Experimentally, leakage current may be affected by the structure of the common layer between the sub-pixels SP1 and SP2 disposed adjacent to each other. Therefore, during the inspection process, in the case where the probes PRB1 and PRB2 come into direct contact with the common layer (e.g., the hole transport component, the charge generating layer, etc.) of the emission structure EMS, it may be interpreted that an external factor other than the operation of the light emitting elements LD1 and LD2 affects the leakage current. In contrast, according to an embodiment, since the layers provided under the contacts CNT1 and CNT2 are exposed, the probes PRB1 and PRB2 may acquire information about current flowing to the light emitting elements LD1 and LD2, thereby reducing the aforementioned risk.

Various embodiments of the invention may provide a method of inspecting a display device in which information about leakage current can be clearly identified.

Hereinafter, an electronic device 1000 including the inspection-target display device TD in accordance with an embodiment will be described.

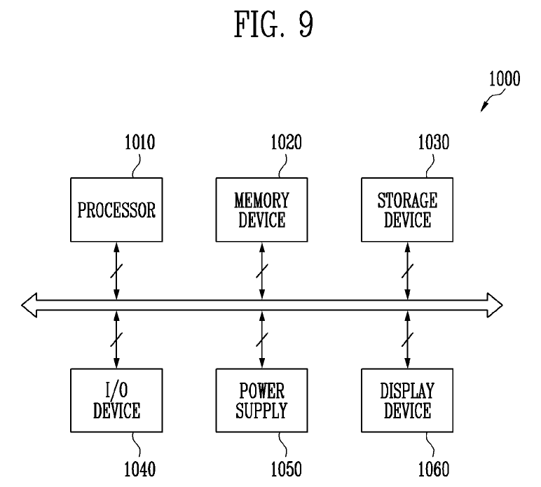

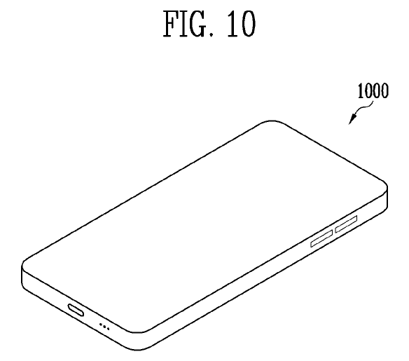

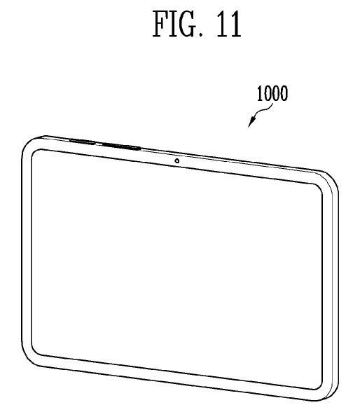

FIG. 9 is a schematic block diagram illustrating an electronic device 1000 including a display device in accordance with an embodiment. FIG. 10 is a schematic diagram illustrating an example where the electronic device 1000 of FIG. 9 is implemented as a smartphone. FIG. 11 is a schematic diagram illustrating an example where the electronic device 1000 of FIG. 9 is implemented as a tablet computer.

Referring to FIGS. 9 to 11, the electronic device 1000 may include a processor 1010, a memory device 1020, a storage device 1030, an input/output (I/O) device 1040, a power supply 1050, and a display device 1060. The display device 1060 may be the inspection-target display device TD of FIG. 1. The electronic device 1000 may further include various ports for communication with a video card, a sound card, a memory card, a USB device, or other systems. In an embodiment, as illustrated in FIG. 10, the electronic device 1000 may be a smartphone. In an embodiment, as illustrated in FIG. 11, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Example embodiments have been disclosed herein, and although specific terms are employed, they are used and are to be interpreted in a generic and descriptive sense only and not for purpose of limitation. In some instances, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention. Thus, while various embodiments have been described above, those skilled in the art will appreciate that various modifications, additions and substitutions are possible, without departing from the scope and spirit of the invention. Therefore, the embodiments disclosed in this specification are only for illustrative purposes rather than limiting the technical spirit of the invention.

What is claimed is:

1. A method of inspecting a display device, comprising:
providing an inspection-target display device including a substrate including a first surface and a second surface, and a first sub-pixel and a second sub-pixel each formed on the first surface of the substrate and disposed adjacent to each other;
performing an etching process directed in a direction from the second surface toward the first surface; and
performing an inspection process on the first sub-pixel and the second sub-pixel,
wherein the first sub-pixel includes a first anode electrode, and a first contactor electrically connected to the first anode electrode, and wherein the second sub-pixel includes a second anode electrode, and a second contactor electrically connected to the second anode electrode,
wherein performing the etching process further comprises exposing the first contactor and the second contactor, and
wherein performing the inspection process further comprises bringing a first probe into electrical contact with the first contactor and bringing a second probe into electrical contact with the second contactor.

2. The method according to claim 1, further comprising performing a pretreatment process on the substrate before performing the etching process,
wherein performing the pretreatment process comprises reducing a thickness of the substrate.

3. The method according to claim 2, wherein the pretreatment process comprises a polishing process or an etching process.

4. The method according to claim 3, wherein the substrate includes silicon.

5. The method according to claim 3, wherein after the pretreatment process is performed, the substrate has a thickness ranging from about 100 μm to about 200 μm.

6. The method according to claim 1,
wherein the inspection-target display device further includes a buffer layer disposed on the substrate, an interlayer conductive layer disposed on the buffer layer, and an insulating layer disposed on the interlayer conductive layer, and
wherein performing the etching process further comprises etching at least a portion of each of the substrate, the buffer layer, the interlayer conductive layer, and the insulating layer.

7. The method according to claim 6,
wherein performing the etching process further comprises performing a first etching process,
wherein performing the first etching process comprises forming a cavity in the substrate such that the buffer layer is not exposed.

8. The method according to claim 7, wherein a depth of the cavity ranges from about 50 μm to about 90 μm.

9. The method according to claim 7,
wherein performing the etching process further comprises performing a second etching process,
wherein performing the second etching process comprises removing at least a portion of each of the substrate and the buffer layer such that at least a portion of the interlayer conductive layer is exposed.

10. The method according to claim 9,
wherein performing the etching process further comprises performing a third etching process,
wherein performing the third etching process comprises removing at least a portion of the insulating layer such that the first contactor and the second contactor are exposed.

11. The method according to claim 10,
wherein the interlayer conductive layer comprises a first conductive layer, a second conductive layer, and a third conductive layer that are sequentially stacked, and
wherein performing the third etching process further comprises etching the first conductive layer, the second conductive layer, and the third conductive layer.

12. The method according to claim 1, wherein each of the first probe and the second probe comprise a nanoprobe or a microprobe.

13. The method according to claim 1, wherein each of the first probe and the second probe have a thickness which is less than a thickness of each of the first contactor and the second contactor.

14. The method according to claim 13, wherein each of the first probe and the second probe includes a tip having a size ranging from about 5 nm to about 15 nm.

15. The method according to claim 1, wherein performing the inspection process further comprises determining information about leakage current between the first sub-pixel and the second sub-pixel, based on quantitative information acquired by the first probe and the second probe.

16. The method according to claim 15,
wherein the first sub-pixel includes a first light emitting element including the first anode electrode,
wherein the second sub-pixel includes a second light emitting element including the second anode electrode, and
wherein performing the inspection process further comprises measuring a magnitude of a first current applied to the first light emitting element, and measuring a magnitude of a second current applied to the second light emitting element.

17. The method according to claim 16, wherein the quantitative information includes the magnitude of the first current and the magnitude of the second current.

18. The method according to claim 1, wherein the inspection-target display device is configured to emit light in a direction that is directed from the second surface toward the first surface.

19. The method according to claim 18,
wherein the inspection-target display device further includes an emission structure disposed on the first anode electrode and the second anode electrode to be directed in a direction from the second surface toward the first surface, and
wherein performing the etching process further comprises exposing the first contactor and the second contactor without removing the emission structure.

20. The method according to claim 19, wherein the emission structure has a tandem structure.

21. An electronic device, comprising:
a processor configured to provide input image data;
the inspection-target display device of claim 1, the inspection-target display device being configured to display an image based on the input image data, the display device including sub-pixel areas; and
a power supply configured to supply power to the display device.
